(19) United States
(12) Patent Application Publication
(10) Pub. No.: US 2025/0270106 A1
(43) Pub. Date: Aug. 28, 2025

(54) JET MIXER REACTOR

(71) Applicant: Mehrdad Alibouri, Behbahan (IR)

(72) Inventor: Mehrdad Alibouri, Behbahan (IR)

(73) Assignee: Mehrdad Alibouri, Behbahan (IR)

(21) Appl. No.: 18/859,572

(22) PCT Filed: May 8, 2022
(86) PCT No.: PCT/IB2022/054254

§ 371 Date: Oct. 24, 2024

(51) Int. Cl. C01G 9/02; B01J 19/24; B82Y 40/00

(52) U.S. Cl. CPC C01G 9/02; B01J 19/2415; B82Y 40/00; B01J 2219/00051; B01J 2219/00162; B01J 2219/00164; C01P 2002/72; C01P 2004/03; C01P 2004/12

(57) ABSTRACT

A method for producing metal and metal oxide nanoparticles in a hydrothermal process may include obtaining a nanoparticle slurry by precipitating nanoparticles within a jet mixer reactor, aging obtained nanoparticle slurry, quenching the aged nanoparticle slurry, and functionalization the nanoparticles. A jet mixer reactor may include an enclosure comprising an elongated side-wall extended along a longitudinal axis of the enclosure between a first end of the enclosure and an opposite second end of the enclosure, a first inlet tube extended along the longitudinal axis of the enclosure and connected to the first end of the enclosure, a second inlet tube extended along the longitudinal axis of the enclosure and connected to the second end of the enclosure, and an outlet tube extended perpendicular to the longitudinal axis of the enclosure and connected to the elongated side-wall of the enclosure.

### TECHNICAL FIELD

The present disclosure relates to jet mixer reactors, and particularly relates to a jet mixer and related processes for continuous production of nanoparticles of metal and/or metal-oxides in the form of homogeneous powder or dispersed particles using hydrothermal processes.

### BACKGROUND

A hydrothermal process is a continuous method for producing nanoparticles of metals and metal oxides. High pressure and temperature water in a subcritical or supercritical state is used as process fluid in this method. The solubility of precursors that are to be dissolved in water decrease near critical point of water (Tc: 374° C., Pc: 221 bar) due to a sharp drop in water density and an increase in concentration of [OH⁻]. The decrease in water density and the increase in [OH⁻] concentration is caused by a highly supersaturated media and leads to rapid nucleation of nanoparticles. In a typical continuous hydrothermal process, a supercritical pure water stream (hot stream) contacts a stream of cold aqueous solution of a metal salt (cold stream) with or without modifiers and/or base solutions inside a mixer. Cold stream heats up very quickly to the operating temperature and nanoparticles are synthesized. Reactor products are then cooled by a heat exchanger and the produced nanoparticles may be recovered at the end of the process. The hydrothermal reaction is an instantaneous reaction with a high reaction rate. The average size of nanoparticles produced by this process may increase with an increase in the reaction time. There is, therefore, a need for reducing the reaction time in order to avoid producing large particles. To this end, the product mixture may be cooled very quickly.

The reactor is the most important part of a hydrothermal process. An efficient mixing in contact zone or reactor may allow for an efficient and rapid heat and mass transfer between the two hot and cold streams and a more uniform temperature distribution within the reactor, which may lead to production of highly uniform nanoparticles in terms of size and shape. Since hot and cold streams in a hydrothermal process may have different densities, providing a rapid and efficient mixing within the reactor may pose a challenge. In addition, keeping the aqueous solution cold before mixing the streams in the contact/reaction zone is challenging, due to the fact that some salts may be predicated out of solution even at temperatures near 60° C. Such predication of some salts may lead to the uncontrolled size and shape of the nanoparticles.

Furthermore, a rapid and efficient mixing within a hydrothermal reactor, as well as feeding the cold stream into a hydrothermal reactor with minimum preheating near the reaction zone may allow for keeping the temperature difference between the hot and cold stream high before the contact zone and for rapidly increasing the temperature of the cold stream within the contact zone. Such, large temperature difference between the cold and hot streams before mixing and such quick increase in the temperature of the cold stream in the contact zone may considerably increase the rate of nucleation and may allow for producing small nanoparticles with uniform size distribution.

Most hydrothermal reactors use buoyancy-driven flow caused by the large difference in density of supercritical pure water and metal salt to mix the contents of the reactor. T- or Y-shaped mixers are common hydrothermal reactors for production of nanoparticles. However, utilizing such T- or Y-shaped reactors may not allow for continuous production of nanoparticles on a commercial basis due to the frequent blockage of the reactor and the need for frequent cleaning. Such frequent blockage in T- and Y-shaped reactors is due to precipitation of particles at the inlet of cold stream that contains a metal salt. In addition, heat transfer along T- and Y-shaped reactors may lead to a temperature increase in the reactor walls at the cold side, which may cause precipitation of the nanoparticles on an inner wall of the reactor and subsequently an inlet blockage. Therefore, T- or Y-shaped reactors have poor mixing and heat and mass transfer. In addition, the location of precipitation of particles within such reactors may not be controllable. There are also safety issues associated with these systems.

One way to address the issues associated with T- or Y-shaped hydrothermal reactors may be utilizing counter current and co-current mixing devices that have been developed for mixing two different fluids. Such counter current and co-current mixing devices may utilize a double concentric tube as a reactor. Mixing within such double concentric reactor occurs because of buoyancy effect due to different densities of hot and cold streams. Such double concentric reactors may further be configured to be vertical. The cold stream flows upward within the double concentric reactor to further assist mixing and transferring nanoparticles out of the reactor due to buoyancy effect.

In the counter current and co-current methods, the temperature rises along the reactor vertically, which may lead to production of different sizes of nanoparticles. The average size of nanoparticles is affected significantly by temperature. In addition, in the counter current and co-current methods, the cold stream may experience a preheat area due to its low velocity, which may cause production of nanoparticles with undesirable shapes and sizes.

Hydrothermal reactions are rapid, consequently, heat and mass transfer may play important roles in the production of high-quality nanoparticles. In other words, production of high-quality nanoparticles may be significantly affected by homogeneity of product temperature, concentration, and reaction time. In addition, the product of the hydrothermal process must be rapidly cooled down to avoid further growth of nanoparticles. Furthermore, the product of the hydrothermal process must be capped with a capping agent or functionalizing agent to avoid agglomeration of the nanoparticles. Common reactors utilize a heat exchanger (indirect cooling) such as one or more double pipes to cool down the product. However, the heat transfer time for cooling the products to a certain temperature to terminate the growth of nanoparticles is much longer in comparison to the required reaction time, especially in large scale production. Such long heat transfer period may allow for nanoparticles to continue growing. In another approach, some reactors may utilize capping agent solutions added to the products at the outlet of the reactor to functionalize and cool down the products directly and rapidly at the same time. However, the amount of final suspension flow rate increases dramatically (at least double) and the cost of equipment for inserting the capping agent solution at high pressures and the cost of separation of nanoparticles from water may increase.

There is, therefore, a need for a hydrothermal reactor that may be configured to allow for a rapid temperature increase in the cold stream and minimizing cold stream preheating. There is further a need for a hydrothermal reactor that may be configured to allow for a strong turbulence mixing to ensure establishing a uniform temperature and concentration distribution within the reactor at a short time. There is further a need for a reactor that may allow for a quick cooling of the products to avoid further growth of nanoparticles. There is further a need for functionalizing nanoparticles by utilizing a capping agent solution to avoid agglomeration and to make a stable nanoparticle dispersion or slurry.

### SUMMARY

This summary is intended to provide an overview of the subject matter of the present disclosure and is not intended to identify essential elements or key elements of the subject matter, nor is it intended to be used to determine the scope of the claimed implementations. The proper scope of the present disclosure may be ascertained from the claims set forth below in view of the detailed description and the drawings.

According to one or more exemplary embodiments, the present disclosure is directed to a method for producing metal and metal oxide nanoparticles in a hydrothermal process. An exemplary method may include obtaining a nanoparticle slurry by precipitating nanoparticles within a jet mixer reactor. An exemplary jet mixer reactor may include an enclosure that may include an elongated sidewall that may be extended along a longitudinal axis of an exemplary enclosure between a first end of an exemplary enclosure and an opposite second end of an exemplary enclosure, a first inlet tube that may be connected to an exemplary first end of an exemplary enclosure. An exemplary first inlet tube may be extended along an exemplary longitudinal axis of an exemplary enclosure, where an exemplary first inlet tube may be in fluid communication with an exemplary enclosure. An exemplary jet mixer reactor may further include a second inlet tube that may be connected to an exemplary jet mixer reactor may include second end of an exemplary jet mixer reactor may include enclosure. An exemplary jet mixer reactor may include a second inlet tube that may be extended along an exemplary longitudinal axis of an exemplary enclosure, where an exemplary second inlet tube in fluid communication with an exemplary enclosure. An exemplary jet mixer reactor may further include an outlet tube that may be connected to an exemplary elongated sidewall of an exemplary enclosure. An exemplary outlet tube may be extended perpendicular to an exemplary longitudinal axis of an exemplary enclosure, where an exemplary outlet tube in fluid communication with an exemplary enclosure.

In an exemplary embodiment, precipitating nanoparticles within an exemplary jet mixer reactor may include injecting a metal salt solution jet into the enclosure by pumping the metal salt solution through the first inlet, injecting a hot fluid jet into the enclosure by pumping the hot fluid through the second inlet tube, concurrently discharging the obtained nanoparticle slurry from the outlet tube, quenching the obtained nanoparticle slurry by passing the discharged nanoparticle slurry through a high-pressure back pressure regulator, and functionalizing a vapor phase of the nanoparticle slurry formed after the back pressure regulator by passing the vapor phase through a high concentration of at least one of a water-based capping agent and a solvent-based capping agent.

### BRIEF DESCRIPTION OF THE DRAWINGS

The novel features which are believed to be characteristic of the present disclosure, as to its structure, organization, use and method of operation, together with further objectives and advantages thereof, will be better understood from the following drawings in which a presently exemplary embodiment of the present disclosure will now be illustrated by way of example. It is expressly understood, however, that the drawings are for illustration and description only and are not intended as a definition of the limits of the present disclosure. Embodiments of the present disclosure will now be described by way of example in association with the accompanying drawings in which:

FIG. 1A illustrates a perspective view of a jet mixer reactor, consistent with one or more exemplary embodiments of the present disclosure;

FIG. 1B illustrates a sectional side view of a jet mixer reactor, consistent with one or more exemplary embodiments of the present disclosure;

FIG. 2 illustrates a sectional side view of a top section of a jet mixer reactor, consistent with one or more exemplary embodiments of the present disclosure;

FIG. 3 illustrates a sectional side view of a bottom section of a jet mixer reactor, consistent with one or more exemplary embodiments of the present disclosure;

FIG. 4 illustrates a sectional side view of a middle section of a jet mixer reactor, consistent with one or more exemplary embodiments of the present disclosure;

FIG. 5 illustrates an inlet tube, consistent with one or more exemplary embodiments of the present disclosure;

FIG. 6 illustrates a flow diagram of a hydrothermal process for synthesizing metal and metal oxide nanoparticles, consistent with one or more exemplary embodiments of the present disclosure;

FIG. 7 illustrates a flow chart of a method for producing metal and metal oxide nanoparticles in a hydrothermal process, consistent with one or more exemplary embodiments of the present disclosure;

FIG. 8 Shows the X-ray diffraction (XRD) of the ZnO nanorods at a supercritical water temperature of 421° C., consistent with one or more exemplary embodiments of the present disclosure;

FIG. 9 shows the average crystal size ZnO nanorods at a supercritical water temperature of 421° C., consistent with one or more exemplary embodiments of the present disclosure;

FIG. 10 shows scanning electron microscope (SEM) image of the ZnO nanorods at a supercritical water temperature of 421° C., consistent with one or more exemplary embodiments of the present disclosure;

FIG. 11 shows the XRD of the Fe₂O₃ nanoparticles at supercritical water temperature of 402° C., consistent with one or more exemplary embodiments of the present disclosure;

FIG. 12 shows the average crystal size Fe₂O₃ nanoparticles at supercritical water temperature of 402° C., consistent with one or more exemplary embodiments of the present disclosure;

FIG. 13 shows SEM of Fe₂O₃ nanoparticles at supercritical water temperature of 402° C., consistent with one or more exemplary embodiments of the present disclosure;

FIG. 14 shows the XRD of the CU₃O₄ nanoparticles at supercritical water temperature of 422° C., consistent with one or more exemplary embodiments of the present disclosure; and

FIG. 15 shows the average crystal size CU₃O₄ nanoparticles at supercritical water temperature of 422° C., consistent with one or more exemplary embodiments of the present disclosure.

### DETAILED DESCRIPTION

The novel features which are believed to be characteristic of the present disclosure, as of its structure, organization, use and method of operation, together with further objectives and advantages thereof, will be better understood from the following discussion.

The present disclosure is directed to exemplary embodiments of a jet mixer reactor that may be utilized for continuous production of metal and metal oxide nanoparticles. An exemplary jet mixer reactor may be configured to allow for an intense collision of at least two fluid jet streams of different densities. This way, kinetic energy of an exemplary cold jet stream and an exemplary hot jet stream may be utilized for creating a vigorous mixing within an exemplary jet mixer reactor. One exemplary jet stream may be a hot fluid while the other exemplary jet stream may be a denser aqueous solution. For example, in an exemplary double-jet mixer reactor, one exemplary jet stream may be a supercritical water stream or a supercritical alcohol stream or a supercritical mixture of water and alcohol stream, while the other exemplary jet stream may be a metal salt solution.

An exemplary jet mixer reactor that is to be utilized for performing a hydrothermal reaction may include a rapid mixing stage, where an exemplary cold metal salt solution jet and an exemplary hot water jet may collide and therefore may be rapidly mixed. An exemplary rapid mixing stage of an exemplary jet mixer reactor may be followed by an aging stage, where enough time may be given to an exemplary mixture for a significant portion of an exemplary metal salt to be converted to nanoparticles. For example, an exemplary mixing stage may include two inlets allowing exemplary hot and cold jet streams to enter an exemplary jet mixer reactor and collide with each other and an exemplary aging stage may include a coiled pipe or tube for exemplary metal salts to be almost fully converted into nanoparticles. An exemplary jet mixer reactor may further include a control valve or a high temperature back pressure regulator that may be configured to instantaneously cool down an exemplary nanoparticle slurry obtained from an exemplary aging stage. Such rapid cooling of an exemplary nanoparticle slurry is carried out to prevent further growth of nanoparticles.

An exemplary jet mixer reactor that is to be utilized for performing a hydrothermal reaction may further include a cooling stage at a cold jet stream inlet right before an exemplary cold jet stream may enter a mixing/reaction zone of an exemplary jet mixer reactor. Such exemplary cooling stage may be utilized to ensure that no preheating occurs in an exemplary cold stream jet before an exemplary cold stream jet may enter an exemplary mixing/reaction zone of an exemplary jet mixer reactor. An exemplary cooling stage may include a cold water jacket that may at least partially encompass an exemplary inlet tube that may be utilized for introducing an exemplary cold jet stream into an exemplary mixing/reaction zone. An exemplary cold water jacket may allow for heat transfer between a cold water stream flowing through an exemplary cold water jacket and an exemplary cold metal salt solution flowing through an exemplary inlet tube.

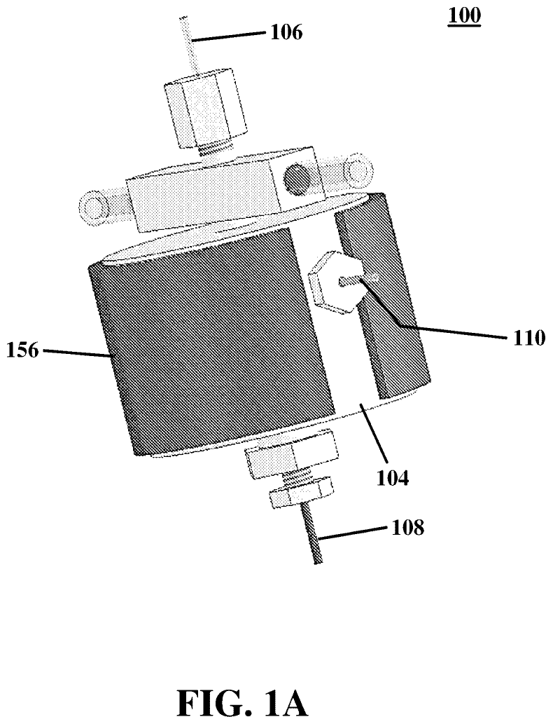

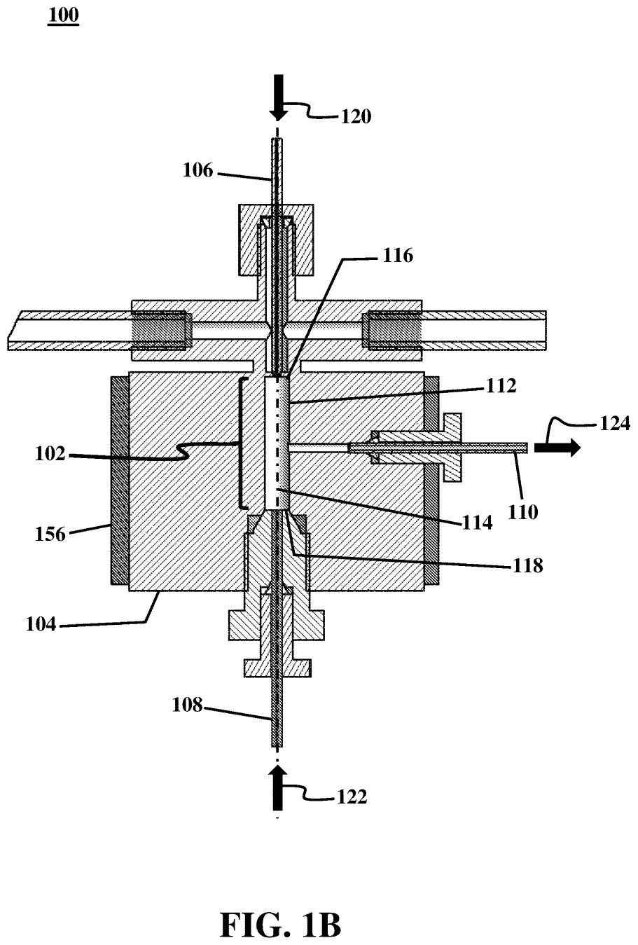

FIG. 1A illustrates a perspective view of a jet mixer reactor 100, consistent with one or more exemplary embodiments of the present disclosure. FIG. 1B illustrates a sectional side view of jet mixer reactor 100, consistent with one or more exemplary embodiments of the present disclosure. In an exemplary embodiment, jet mixer reactor 100 may include a mixing/reaction zone 102 that may be encompassed by a main body 104 of jet mixer reactor 100. In an exemplary embodiment, jet mixer reactor 100 may further include a first inlet tube 106, a second inlet tube 108, and an outlet tube 110 that may all be connected in fluid communication with mixing/reaction zone 102.

In an exemplary embodiment, mixing/reaction zone 102 may be an enclosure that may include an elongated side-wall 112 extended along a longitudinal axis 114 of mixing/reaction zone 102 between a first end 116 of mixing/reaction zone 102 and an opposite second end 118 of mixing/reaction zone 102. In an exemplary embodiment, first inlet tube 106 may include an elongated capillary tube that may be extended along longitudinal axis 114 of mixing/reaction zone 102. In an exemplary embodiment, first inlet tube 106 may be connected to first end 116 of mixing/reaction zone 102 and may be configured to be in fluid communication with an inner volume of mixing/reaction zone 102. In an exemplary embodiment, second inlet tube 108 may include an elongated capillary tube that may be extended along longitudinal axis 114 of mixing/reaction zone 102. In an exemplary embodiment, second inlet tube 108 may be connected to second end 118 of mixing/reaction zone 102 and may be configured to be in fluid communication with an inner volume of mixing/reaction zone 102. Such configuration of mixing/reaction zone 102, first inlet tube 106, and second inlet tube 108 may allow for first inlet tube 106 and second inlet tube 108 to be configured to introduce respective fluid jet streams into mixing/reaction zone 102 from opposing ends (116, 118) of mixing/reaction zone 102 in opposite directions along longitudinal axis 114.

In an exemplary embodiment, outlet tube 110 may be connected to elongated side-wall 112 of mixing/reaction zone 102, where outlet tube 110 may be a tube extended perpendicular to longitudinal axis 114. In an exemplary embodiment, outlet tube 110 may be connected to elongated side-wall 112 at a position between first end 116 and second end 118 of mixing/reaction zone 102. In an exemplary embodiment, outlet tube 110 may be configured to allow for a mixture of fluid jet streams to be discharged from mixing/reaction zone 102 in a direction perpendicular to the directions along which respective fluid jet streams were introduced by utilizing first inlet tube 106 and second inlet tube 108.

In an exemplary embodiment, first inlet tube 106 may be configured to allow for a cold solution jet to be introduced into mixing/reaction zone 102 in a first direction along longitudinal axis 114 of mixing/reaction zone 102. For example, first inlet tube 106 may be configured to allow for an exemplary cold solution jet to be introduced into mixing/reaction zone 102 in a first direction shown by a first arrow 120. In an exemplary embodiment, an exemplary cold solution jet may include a cold metal salt solution. In an exemplary embodiment, such configuration of first inlet tube 106 as a capillary tube may allow for providing a jet of cold metal salt solution through first inlet tube 106. Specifically, a cold solution such as a cold metal salt solution may be pumped from a cold solution source through first inlet tube 106 into mixing/reaction zone 102 and due to the relatively small diameter of first inlet tube 106, the cold metal salt solution may enter mixing/reaction zone 102 as a jet stream.

In an exemplary embodiment, first inlet tube 106 may further be configured to allow for a cold aqueous solution of a metal salt to be introduced into mixing/reaction zone 102 with or without modifiers such as PVP, citric acid and poly (ethylene glycol) and/or base solution such as KOH and NaOH. In an exemplary embodiment, an exemplary cold aqueous solution of a metal salt jet may be pumped into mixing/reaction zone 102 via first inlet tube 106 with a pressure adjusted in a range of 70 to 400 bar and a temperature of at most 40° C. For example, an exemplary metal salt solution may include an aqueous solution of Zn(NO₃)₂ that may be injected into mixing/reaction zone 102 of jet mixer reactor 100 for synthesizing zinc oxide nanoparticles. In another example, an exemplary metal salt solution may include an aqueous solution of Fe(NO₃)₂ that may be injected into mixing/reaction zone 102 of jet mixer reactor 100 for synthesizing iron oxide (Fe₂O₃) nanoparticles. In yet another example, an exemplary metal salt solution may include an aqueous solution of Cu(NO₃)₂ that may be injected into mixing/reaction zone 102 of jet mixer reactor 100 for synthesizing copper oxide (CU₃O₄) nanoparticles. In addition to the above-mentioned examples, an exemplary metal salt solution may be chosen based on the type of nanoparticles that are to be synthesized by performing a hydrothermal process within jet mixer reactor 100.

In an exemplary embodiment, second inlet tube 108 may be configured to allow for a hot fluid jet to be introduced into mixing/reaction zone 102 in a second direction along longitudinal axis 114 of mixing/reaction zone 102. For example, second inlet tube 108 may be configured to allow for an exemplary hot fluid jet to be introduced into mixing/reaction zone 102 in a second direction shown by a second arrow 122. In an exemplary embodiment, an exemplary hot fluid jet may include a hot pure water jet, an alcohol jet or a mixture of water and alcohol jet. In an exemplary embodiment, such configuration of second inlet tube 108 as a capillary tube may allow for providing a strong hot water jet through second inlet tube 108. Specifically, a hot fluid such as hot water may be pumped from a hot fluid source through second inlet tube 108 into mixing/reaction zone 102 and due to the relatively small diameter of second inlet tube 108, the hot water may enter mixing/reaction zone 102 as a jet stream. In an exemplary embodiment, an exemplary hot fluid jet may include supercritical water, alcohol or a mixture of water and alcohol that may be pumped into mixing/reaction zone 102 via second inlet tube 108 at a pressure adjusted in a range of 70 to 400 bar and a temperature adjusted in a range of 200 to 550° C.

In an exemplary embodiment, such injection of an exemplary cold metal salt solution jet via first inlet tube 106 and a hot fluid jet via second inlet tube 108 into mixing/reaction zone 102 in opposite first and second directions as shown by arrows (120, 122) may allow for cold and hot jets to collide in a very small, confined space of mixing/reaction zone 102, which ensures a vigorous mixing of an exemplary cold metal salt solution jet and an exemplary hot fluid jet. As mentioned before, such vigorous mixing within mixing/reaction zone 102 may allow for an instantaneous increase in the temperature of exemplary cold metal salt solution up to the operating temperature at which nanoparticles may form within mixing/reaction zone 102.

In an exemplary embodiment, outlet tube 110 may be configured to allow for a slurry of nanoparticles formed within mixing/reaction zone 102 to be discharged out of mixing/reaction zone 102 in a third direction perpendicular to longitudinal axis 114 of mixing/reaction zone 102. For example, outlet tube 110 may be configured to allow for an exemplary slurry of nanoparticles to be discharged out of mixing/reaction zone 102 in a third direction shown by a third arrow 124.

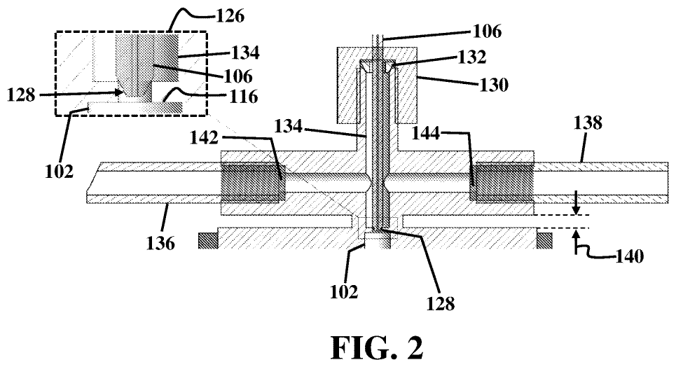

FIG. 2 illustrates a sectional side view of a top section of jet mixer reactor 100, consistent with one or more exemplary embodiments of the present disclosure. In an exemplary embodiment, first inlet tube 106 may be connected to mixing/reaction zone 102 in a fully sealed manner with a minimum common surface area between first inlet tube 106 and first end 116 of mixing/reaction zone 102. As used herein, a fully sealed manner may refer to a connection between first inlet tube 106 and mixing/reaction zone 102, where the fluid communication is only between first inlet tube 106 and mixing/reaction zone 102 without any leak to surrounding environment. In an exemplary embodiment, a minimum common surface area between first inlet tube 106 and first end 116 of mixing/reaction zone 102 may be achieved by forming a connecting end 128 of first inlet tube 106 into a conc. For example, connecting end 128 of first inlet tube 106 may be machined into a cone, where a diameter of first inlet tube 106 may decrease to a minimum acceptable diameter, where first inlet tube 106 is to be connected to mixing/reaction zone 102. Such cone-shape formation for connecting end 128 of first inlet tube 106 is illustrated in an inset 126 of FIG. 2.

In practice, a first UNF nut 130 and a first ferrule 132 may be utilized for connecting first inlet tube 106 to mixing/reaction zone 102. In an exemplary embodiment, first UNF nut 130 and first ferrule 132 may be configured to supply the required force for scaling connecting end 128 of first inlet tube 106 to first end 116 of mixing/reaction zone 102. In exemplary embodiments, such cone-shaped formation of connecting end 128 of first inlet tube 106 and how cone-shaped formation of connecting end 128 of first inlet tube 106 may be utilized for sealing the connection between first inlet tube 106 and mixing/reaction zone 102 may be similar to cone-shaped sealings that are utilized in commercial needle valves, where a cone-shaped plunger provides a full scaling up to pressures of 1000 bar even in response to a relatively small force exerted on an exemplary cone-shaped plunger.

In an example, first inlet tube 106 may include a 1/16 inch capillary tube with an outer diameter of 1.59 mm and an inner diameter of 127 pm that may be connected to mixing/reaction zone 102 by utilizing first ferrule 132 and first UNF nut 130, where first ferrule 132 includes a ⅛ inch ferrule and first UNF nut 130 includes a ¼ inch UNF nut. In an exemplary embodiment, first UNF nut 130 and first ferrule 132 may seal inlet tube 106 against water leakage from water jacket 134. In fact, first UNF nut 130 and first ferrule 132 may supply the required force for sealing connecting end 128 of first inlet tube 106 to first end 116 of mixing/reaction zone 102 to avoid leakage of reactor fluid at cone-shape point (128) and simultaneously may supply the required force for sealing inlet tube 106 against water leakage of water jacket 134 at the location of first ferrule 132.

In an exemplary embodiment, as mentioned before, first inlet tube 106 may be configured to provide a cold metal salt solution jet into mixing/reaction zone 102, where an exemplary cold metal salt solution jet may collide with a counter hot fluid jet within mixing/reaction zone 102. Such instantaneous collision between an exemplary cold metal salt solution jet with an exemplary counter hot fluid jet is ideal for rapidly increasing the temperature of an exemplary cold metal salt solution up to an operating temperature where nanoparticles may form within mixing/reaction zone 102. In practice, any unwanted preheating of an exemplary cold metal salt solution before the collision of an exemplary cold metal salt solution jet and an exemplary counter hot fluid jet may lead to unwanted and undesirable formation of nanoparticles within first inlet tube 106. Such unwanted and undesirable formation of nanoparticles within first inlet tube 106 may lead to problems such as blockage of first inlet tube 106. Consequently, in an exemplary embodiment, first inlet tube 106 may be kept cold to the closest possible point to first end 116 of mixing/reaction zone 102. To this end, in an exemplary embodiment, a cold water jacket 134 may be provided around first inlet tube 106, where a stream of cold water may enter cold water jacket 134 from a jacket inlet tube 136 and may contact at least a portion of an outer surface of first inlet tube 106. Then, the cold water may leave cold water jacket 134 through a jacket outlet tube 138.

In an exemplary embodiment, jacket inlet tube 136 may be connected to cold water jacket 134 by utilizing a first copper gasket 142 that may ensure a sealed connection between jacket inlet tube 136 and cold water jacket 134. In an exemplary embodiment, jacket outlet tube 138 may be connected to cold water jacket 134 by utilizing a second copper gasket 144 that may ensure a sealed connection between jacket outlet tube 138 and cold water jacket 134. In an exemplary embodiment, jacket inlet tube 136 and jacket outlet tube 138 may include ¼ inch tubes with ¼ inch UNF threads. In an exemplary embodiment, a gap 140 may be provided between outer surfaces of jacket inlet and outlet tubes (136, 138) and main body 104 to further minimize the chances of heat transfer between hot mixing/reaction zone 102 and jacket inlet and outlet tubes (136, 138).

Referring to inset 126 of FIG. 2, in an exemplary embodiment, cold water jacket 134 may be extended along first inlet tube 106 to encompass the outer surface of first inlet tube 106 to connecting end 128 of first inlet tube 106, which is the closest point to where first inlet tube 106 may be attached to first end 116 of mixing/reaction zone 102. Furthermore, as mentioned before and as is evident from inset 126, cone-shaped connecting end 128 of first inlet tube 106 may allow for having a relatively smaller cross-sectional area between first inlet tube 106 and first end 116 of mixing/reaction zone 102, which further reduces the chance of heat transfer between hot mixing/reaction zone 102 and cold first inlet tube 106.

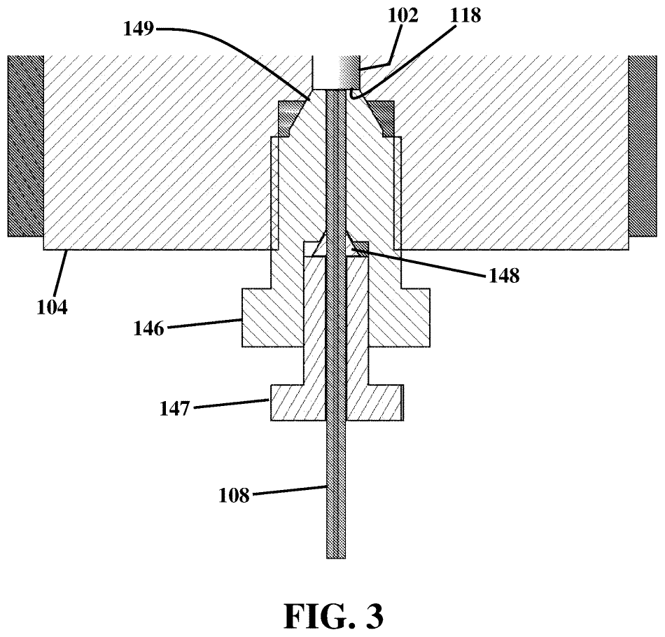

FIG. 3 illustrates a sectional side view of a bottom section of jet mixer reactor 100, consistent with one or more exemplary embodiments of the present disclosure. In an exemplary embodiment, second inlet tube 108 may be connected to mixing/reaction zone 102 in a fully sealed manner. As used herein, a fully sealed manner may refer to a connection between second inlet tube 108 and mixing/reaction zone 102, where the fluid communication is only between second inlet tube 108 and mixing/reaction zone 102 without any leak to surrounding environment. In practice, there may be two scaling points (or areas) for avoiding fluid leakage mixing/reaction zone 102. First, sealing of nut 146 to main body 104 at the location of cone-shape area of nut 146 (designated by reference numeral 149 in the FIG. 3). In an exemplary embodiment, nut 146 exerts a force onto cone-shaped area 149 in response to being tightened or fastened and thereby may make a reliable seal at that location. Second, scaling of second inlet tube 108 by utilizing a small nut 147 and ferrule 148 at the location of ferrule 148. In an example, second inlet tube 108 may include a 1/16 inch capillary tube with an outer diameter of 1.59 mm and an inner diameter of 127 pm that may be connected to mixing/reaction zone 102 by utilizing a small nut 147, a ferrule 148 and a nut 146, where small nut 147 may include a ¼ inch UNF nut, ferrule 148 may include a 1/16 inch ferrule, and nut 146 may include a 7/16 inch cone-shaped UNF nut. In an exemplary embodiment, second inlet tube 108 may be fully supported and scaled by utilizing UNF nut 147, ferrule 148 and cone-shaped UNF nut 146, which may allow for a high speed jet of fluid to be introduced into mixing/reaction zone 102 by utilizing second inlet tube 108 without any unwanted undesirable vibrations. This may be in contrast with prior art devices that utilize unsupported long tubes for introduction of fluids into exemplary prior art devices. Such unsupported long tubes may severely vibrate if a high speed jet is to be injected therethrough.

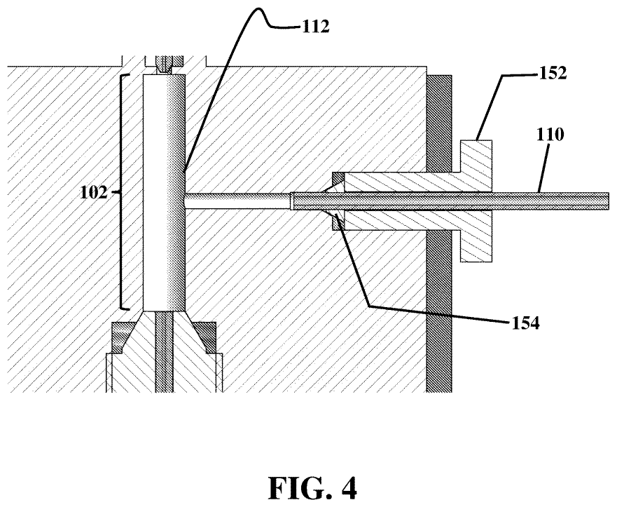

FIG. 4 illustrates a sectional side view of a middle section of jet mixer reactor 100, consistent with one or more exemplary embodiments of the present disclosure. In an exemplary embodiment, outlet tube 110 may be connected to mixing/reaction zone 102 in a fully scaled manner. As used herein, a fully sealed manner may refer to a connection between outlet tube 110 and ferrule 154, where the fluid communication is only between outlet tube 110 and mixing/reaction zone 102 without any leak to surrounding environment. In practice, outlet tube 110 may be sealed by utilizing a nut 152 and ferrule 154 at the location of ferrule 154 by tightening nut 152 to exert force onto ferrule 154. There is no sealing between outlet tube 110 and elongated side-wall 112. In an example, outlet tube 110 may include a 1/16 inch capillary tube with an inner diameter of 790 pm that may be connected to mixing/reaction zone 102 by utilizing ferrule 154 and UNF nut 152, where ferrule 154 includes a 1/16 inch ferrule and UNF nut 152 includes a ¼ inch UNF nut.

In an exemplary embodiment, to get a better sense of the operating conditions of an exemplary jet mixer reactor similar to jet mixer reactor 100, a ratio of the flow rate of a cold metal salt solution jet introduced into mixing/reaction zone 102 by utilizing first inlet tube 106 to the flowrate of a supercritical waterjet introduced into mixing/reaction zone 102 by utilizing second inlet tube 108 may be assumed to be in a range of 0.2 to 1. For example, the flowrate of the supercritical water jet may be half the flow rate of the supercritical water jet. In other words, a ratio of the flow rate of an exemplary supercritical water jet to the flow rate of an exemplary cold metal salt solution jet may be 2. For example, a flow rate of a cold metal salt solution jet may be 4 mL/min and a flow rate of a supercritical water jet may be 8 mL/min. Assuming that the density of a dilute metal oxide solution and pure water at ambient condition may be considered to be 1 g/ml, then the mass flow rates of the two exemplary cold metal salt solution jet and supercritical water jet may be 4 g/mL and 8 g/mL, respectively. Here, the velocity of an exemplary cold metal salt solution jet passing through first inlet tube 106 may be adjusted at a velocity of at least 3 m/s. For example, the velocity of an exemplary cold metal salt solution jet passing through first inlet tube 106 with a diameter of 0.127 mm may be adjusted to be 5.26 m/s. Such exemplary cold metal salt solution jet at this velocity may be considered a strong jet.

In this example, pressure of an exemplary supercritical water jet passing through second inlet tube 108 at the entrance to mixing/reaction zone 102 may be the same as pressure of jet mixer reactor outlet which for the sake of this example may be 240 bar. Here, an exemplary supercritical water jet passing through second inlet tube 108 may have a temperature of approximately 420° C. and a density of 0.122 g/ml at this temperature. In this example, the velocity of an exemplary supercritical waterjet passing through second inlet tube 108 may be adjusted at a velocity of at least 10 m/s. For example, the velocity of an exemplary supercritical waterjet passing through second inlet tube 108 with an internal diameter of 0.127 mm may be calculated to be approximately 86.27 m/s. Such exemplary supercritical water jet at this calculated velocity may be considered a strong jet.

In this example, mixing/reaction zone 102 may be considered to be an enclosure with an internal diameter of 4 mm and a height of 22.5 mm, which provides an internal volume of 0.283 mL. Consequently, an exemplary cold metal salt solution jet and an exemplary supercritical waterjet may collide in a confined space with a height of 22.5 mm, which makes their collision a severe one. Such severe collision of an exemplary cold metal salt solution jet and an exemplary supercritical water jet may allow for mixing the aforementioned jets in a very short time. For example, in the conditions described in this paragraph and the preceding paragraph, total mass flow rate into mixing/reaction zone 102 may be 12 g/min and the average temperature of mixing may be approximately 376.7° C. Consequently, density and flow rate of the obtained nanoparticle slurry may be calculated to be approximately 0.464 g/mL and 25.86 mL/min, respectively. Here, the residence time within mixing/reaction zone 102 calculated based on the volume of mixing/reaction zone 102 and mass flow rate of the obtained nanoparticle slurry may be 0.66 seconds.

As mentioned before, in order to prevent further growth of nanoparticles within the obtained nanoparticle slurry, which is discharged from outlet tube 110 of jet mixer reactor 100, the obtained nanoparticle slurry must be quenched. In the example of the preceding paragraph, an exemplary nanoparticle slurry may be transferred to a small double pipe heat exchanger to cool down to a temperature of approximately 50° C. An exemplary double pipe exchanger may include two concentric pipes, where an exemplary slurry may flow through an exemplary inner pipe and tap water may flow in an exemplary outer pie. In this example, a length of an exemplary double pipe heat exchanger may be 12 cm. Here, the average density of an exemplary nanoparticle slurry between the inlet and outlet of the exchanger may be 0.732 g/ml. The nanoparticle slurry flow rate may be 12 g/min, and the average volumetric flow rate of the nanoparticle slurry may be 16.39 mL/min. Consequently, the holdup for a 10 cm tube with a 0.79 mm internal diameter may be calculated to be 0.049 mL. Therefore, the residence time for an exemplary nanoparticle slurry in an exemplary heat exchanger may be just about 0.18 s, which obviously may be considered a quick quenching for small scale jet mixer reactors, such as jet mixer reactor 100. This example shows that an exemplary jet mixer reactor structurally similar to jet mixer reactor 100 may allow for both a rigorous and instantaneous mixing of an exemplary cold metal oxide solution and an exemplary supercritical water jet to form a nanoparticle slurry that may be quickly discharged and cooled down in a matter of less than a second.

Referring to FIGS. 1A and IB, in an exemplary embodiment, jet mixer reactor 100 may further include an auxiliary heater 156 that may be mounted on an outer surface of main body 104 to keep main body 104 hot. In an exemplary embodiment, auxiliary heater 156 may include a band heater mounted on the outer surface of main body 104 and controlled by a temperature control system that may be configured to keep the temperature of main body 104 at a predetermined set point. In an exemplary embodiment, such utilization of auxiliary heater 156 may be necessary due to the fact that mass of main body 104 may be much more than the mass of hot supercritical water and cold metal salt solution within jet mixer reactor 100 and consequently heat transfer to main body 102 may be too high. As a result, heat loss to the environment through main body 102 may be too high and auxiliary heater 156 may be utilized to prevent that.

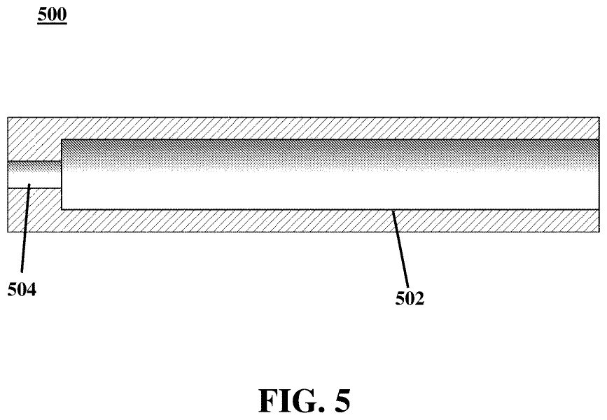

FIG. 5 illustrates an inlet tube 500, consistent with one or more exemplary embodiments of the present disclosure. In an exemplary embodiment, for larger operations and higher flow rates, first inlet tube 106 and second inlet tube 108 may be configured to be structurally similar to inlet tube 500. In an exemplary embodiment, inlet tube 500 may include two sections, a first section 502 and a second section 504, that may be attached to or integrally formed with each other. In an exemplary embodiment, first section 502 may have a larger diameter to be able to handle larger mass flow rates without pressure drop and second section 504, which may have a smaller diameter and smaller length in comparison with first section 502 may be designed as a capillary tube through which a high speed jet of fluid may be formed and injected into jet mixer reactor 100. For example, for injecting an exemplary hot fluid jet, first section 502 may be a ½ inch tube with an inner diameter of 8.5 mm and second section 504 may have an inner diameter of 2.2 mm and a length of 3 mm. In another example, for injecting a cold solution jet, first section 502 may be a ¼ inch tube with an inner diameter of 3.9 mm and second section 504 may have an inner diameter of 1 mm and a length of 3 mm.

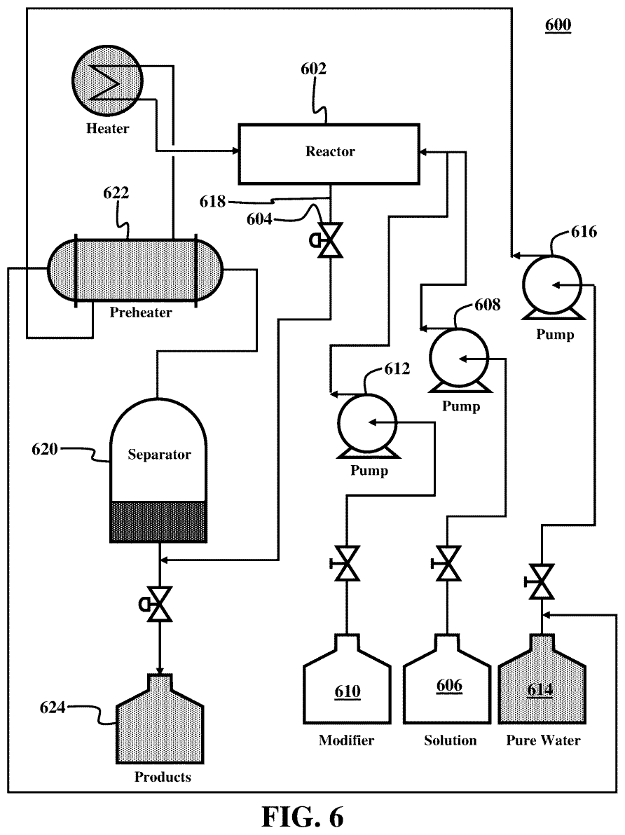

FIG. 6 illustrates a flow diagram of a hydrothermal process 600 for synthesizing metal and metal oxide nanoparticles, consistent with one or more exemplary embodiments of the present disclosure. In an exemplary embodiment, hydrothermal process 600 may include a jet mixer reactor 602 that may be structurally similar to jet mixer reactor 100. As discussed before, in order to prevent further growth of nanoparticles within the obtained product, which may include a nanoparticle slurry, the obtained nanoparticle slurry must be quenched. In an exemplary embodiment, a nanoparticle slurry which may be discharged from jet mixer reactor 602 may pass through a back pressure regulator 604 where the temperature of the nanoparticle slurry instantaneously. In an exemplary embodiment, an exemplary nanoparticle slurry may be converted into a two-phase flow after passing through back pressure regulator 604 at ambient pressure. Since the concentration of exemplary nanoparticles in an exemplary nanoparticle slurry may be very low, an exemplary two-phase flow may be considered to include pure water at ambient pressure. Considering this, the temperature of the two-phase flow stream may be the boiling point of water at ambient pressure, which is 100° C. Consequently, the temperature of an exemplary nanoparticle slurry may drop from 370° C. before back pressure regulator 604 to 100° C. after passing through back pressure regulator 604.

In an exemplary embodiment, an exemplary cold solution jet that may be injected into jet mixer reactor 602 may include a mixture of a metal salt solution pumped into jet mixer reactor 602 from a solution reservoir 606 by utilizing a solution pump 608 and an exemplary modifier pumped into jet mixer reactor 602 from a modifier reservoir 610 by utilizing a modifier pump 612. In an exemplary embodiment, an exemplary hot fluid jet, such as a hot supercritical waterjet may be pumped into jet mixer reactor 602 from a water reservoir 614 by utilizing a solution pump 616. In a case study, the flow rates of an exemplary cold metal salt solution may be 1 L/min and the flowrate of an exemplary hot supercritical waterjet may be 2 L/min. A nozzle that may be structurally similar to inlet tube 500 may be utilized for injecting an exemplary hot supercritical waterjet into jet mixer reactor 602. Here, first section 502 may be a ½ inch tube with an inner diameter of 8.5 mm and second section 504 may have an inner diameter of 2.2 mm and a length of 3 mm. In an exemplary embodiment, an exemplary hot supercritical water jet may have a temperature of approximately 450° C. In an exemplary embodiment, the pressure drop, and the velocity of an exemplary hot supercritical water jet may be calculated to be 9.6 bar and 80.5 m/s, respectively. Here in this case study, the pressure within jet mixer reactor 602 may be set at 240 bar, which means the pressure of an exemplary hot supercritical water in section 502 right before section 504 may be approximately 249.6 bar.

A nozzle that may be structurally similar to inlet tube 500 may be utilized for injecting an exemplary cold metal salt solution jet into jet mixer reactor 602. Here, first section 502 may be a ¼ inch tube with an inner diameter of 3.9 mm and second section 504 may have an inner diameter of 1 mm and a length of 3 mm. In an exemplary embodiment, the pressure drop, and the velocity of an exemplary cold metal salt solution jet may be calculated to be 6 bar and 21.2 m/s, respectively. The pressure of an exemplary cold metal salt solution in section 502 right before section 504 may be approximately 246 bar.

In this case study, jet mixer reactor 602 may include a mixing/reaction zone similar to mixing/reaction zone 102 of jet mixer reactor 100. In an exemplary embodiment, mixing/reaction zone of jet mixer reactor 602 may have a diameter of 12.7 mm and a length of 20.5 mm, which may provide a mixing/reaction zone with a volume of approximately 2.59 mL. Residence time within mixing/reaction zone of jet mixer reactor 602 based on the conditions described in the present case study may be approximately 0.02 s. Due to such short residence time within jet mixer reactor 602, there may be no need for a band heater to be installed around jet mixer reactor 602. The discharged product from jet mixer reactor 602 may have a temperature of approximately 380° C., a pressure of approximately 240 bar, and a density of approximately 0.386 g/mL. In this case study, a coiled aging tube 618, in which enough time may be given to an exemplary product for a significant portion of an exemplary metal salt to be converted to nanoparticles. In an exemplary embodiment, coiled aging tube 618 may include a coiled insulated ½ inch tube with an internal diameter of 8.5 mm. Here, the pressure drop within coiled aging tube 618 may be calculated to be approximately 0.08 bar, the fluid velocity within coiled aging tube 618 may be calculated to be approximately 2.28 m/s, and the Reynolds number and residence time within coiled aging tube 618 may be calculated to be approximately 163878 and 1.75 s, respectively. Such high Reynolds number may be indicative of a turbulent flow within coiled aging tube 618, which may be beneficial in terms of efficient mixing within the aging section.

In this case study, according to an exemplary embodiment of the present disclosure, the obtained aged product may flow through high-temperature back pressure regulator 604, where the temperature of the product may suddenly decrease and the product may be separated in to two phases. In an exemplary embodiment, vapor fraction of the saturated steam of the water after back pressure regulator 604 is high (saturated liquid and vapor at boiling point of 100° C.) and most part of the two-phase stream is vapor. This flow stream enters a separator 620 and passes through a high concentration solution of a capping agent such as PVP, citric acid and poly (ethylene glycol) in water or an organic solvent such as Oleic acid and Oleylamine within separator 620 for functionalization of the nanoparticles to avoid agglomeration. In this case study, the vapor fraction of the product may be 0.9755. Here the vapor phase may include a high percentage of water, consequently, after back pressure regulator 604 a large portion of water may be separated from final product as water vapor. The water vapor after separator 620 may pass through a preheater 622 and may be sent back to water reservoir 614. In an exemplary embodiment, the residence time within separator 620 may be 5 min. The flowrate of the product may be 3 L/min, consequently, the required volume of separator 620 to allow for a residence time of 5 min and a 50% occupied volume may be 30 L. After separation of water vapor within separator 620, a thick nanoparticle slurry maybe discharged from the bottom of separator 620 into a product tank 624. Then, nanoparticles may be separated and washed from the thick slurry with minimum cost and producing no significant wastewater. As mentioned earlier, the separated water vapor may first pass through preheater 622, where the latent heat of the vapor may be recovered to preheat the pure water stream provided from water reservoir 614.

In an exemplary embodiment, a capping agent solution may be introduced to jet mixer reactor 602 as an independent stream or mixed with a metal salt solution. For example, an exemplary caping agent may be stored in a modifier reservoir 610 and may be pumped by utilizing modifier pump 612 directly into jet mixer reactor 602 or may be mixed with a metal salt solution stream provided from solution reservoir 606 and then injected into jet mixer reactor 602. However, in another exemplary embodiment, instead of injecting the aging agent from modifier reservoir 610, separator 620 may be loaded with 15 L of high concentration of an exemplary capping agent solution, such as 10% PVP dissolved in water at 100° C. In this condition, the concentration of the PVP (10% wt.) is high and the nanoparticles have enough time to contact with PVP and become effectively functionalized. Moreover, there is no risk of decomposition of PVP at 100° C. Then, functionalized nanoparticles slurry maybe stored as a high concentration water based source of nanoparticles for making diluted stable water based dispersions or maybe separated and washed from thick slurry with minimum cost and no significant wastewater.

In another exemplary embodiment, the produced nanoparticles may be functionalized by utilizing an organic solvent, such as oleic acid and oleylamine, which may similarly be added to separator 620. Oleic acid does not dissolve in water. In this condition the nanoparticles of the product flow remain in oleic acid and water leaves separator 620 at 100° C. as vapor. Then a thick slurry of the nanoparticles in oleic acid with small amounts of water may be discharged from separator 620. Then, functionalized nanoparticles slurry maybe stored as a high concentration solvent based source of nanoparticles for making diluted stable solvent based dispersions or maybe separated and washed from thick slurry with minimum cost and no significant wastewater. In an exemplary embodiment, various capping agents may be utilized in this process at temperatures around 100° C. without the risk of thermal decomposition. In this process configuration, the nanoparticles are well functionalized with a high ratio of the capping agent to the nanoparticles, to produce stable dispersion. In exemplary embodiment, hydrothermal process 600 may allow for producing stable dispersions of nanoparticles with a high ratio of the caping agent to nanoparticles.

According to one or more exemplary embodiments, the present disclosure is further directed to a method for producing metal and metal oxide nanoparticles in a hydrothermal process. In an exemplary embodiment, an exemplary method for synthesizing or producing metal and metal oxide nanoparticles may be carried out in an exemplary hydrothermal process similar to hydrothermal process 600 that may utilize an exemplary jet mixer reactor similar to jet mixer reactor 100.

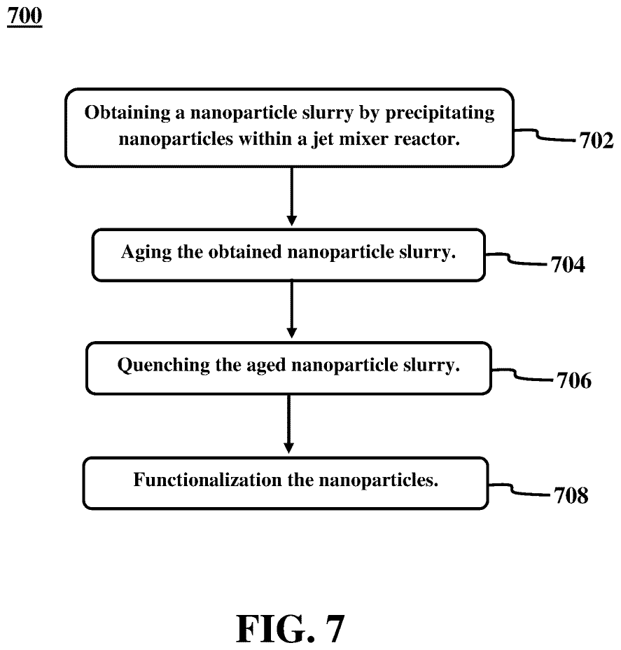

FIG. 7 illustrates a flow chart of a method 700 for producing metal and metal oxide nanoparticles in a hydrothermal process, consistent with one or more exemplary embodiments of the present disclosure. In an exemplary embodiment, method 700 may include a step 702 of obtaining a nanoparticle slurry by precipitating nanoparticles within a jet mixer reactor, a step 704 of aging the obtained nanoparticle slurry, a step 706 of quenching the aged nanoparticle slurry, and a step 708 of functionalization the nanoparticles.

In an exemplary embodiment, step 702 of obtaining the nanoparticle slurry may include precipitating nanoparticles within a jet mixer reactor that may be structurally similar to jet mixer reactor 100. In an exemplary embodiment, step 702 of obtaining the nanoparticle slurry may include injecting a metal salt solution jet into an enclosure of an exemplary jet mixer reactor similar to mixing/reaction zone 102 of jet mixer reactor 100. To this end, an exemplary metal salt solution may be pumped out of a metal salt solution reservoir by utilizing a pump into an exemplary enclosure of an exemplary jet mixer reactor. For example, a metal salt solution may be pumped out of solution reservoir 606 by utilizing solution pump 608 through first inlet tube 106 into mixing/reaction zone 102.

In an exemplary embodiment, step 702 of obtaining the nanoparticle slurry may further include injecting a hot waterjet into an enclosure of an exemplary jet mixer reactor similar to mixing/reaction zone 102 of jet mixer reactor 100. To this end, an exemplary hot water may be pumped out of a water reservoir by utilizing a pump into an exemplary enclosure of an exemplary jet mixer reactor. For example, hot water may be pumped out of water reservoir 614 by utilizing water pump 616 through second inlet tube 108 into mixing/reaction zone 102.

In an exemplary embodiment, step 702 of obtaining the nanoparticle slurry may include collision of the injected metal salt solution jet and the injected hot fluid jet within an exemplary enclosure of an exemplary jet mixer reactor. Such collision may allow for a vigorous mixing of an exemplary metal salt solution and an exemplary hot fluid which may lead to an instantaneous increase in the temperature of cold metal salt solution. Such increase in the temperature of metal salt solution may lead to precipitation of nanoparticles within an exemplary enclosure of an exemplary jet mixer reactor.

In an exemplary embodiment, step 702 of obtaining the nanoparticle slurry may further include concurrently discharging the obtained nanoparticle slurry from an exemplary enclosure of an exemplary jet mixer reactor. For example, the obtained nanoparticle slurry may be concurrently discharged from outlet tube 110 of jet mixer reactor 100. As used herein, concurrently discharging may refer to continuous discharge of the obtained nanoparticle slurry from an exemplary enclosure of an exemplary jet mixer reactor.

In an exemplary embodiment, step 704 of aging the obtained nanoparticle slurry may include discharging the obtained nanoparticle slurry from an exemplary enclosure of an exemplary jet mixer reactor into a coiled aging tube, where enough time is given to the obtained slurry for the precipitation of nanoparticles to be completed.

In an exemplary embodiment, step 706 of quenching the aged nanoparticle slurry may involve passing the aged nanoparticle slurry through a high-pressure back pressure regulator, where the temperature of the aged nanoparticle slurry may instantaneously drop. Such quenching of the obtained nanoparticle slurry is required to prevent further growth of the nanoparticles.

In an exemplary embodiment, step 708 of functionalization the nanoparticles may include passing the quenched nanoparticle stream through a high concentration of a water-based capping agent such as PVP, citric acid and poly (ethylene glycol) or using a solvent based capping agent such as oleic and oleylamine acid kept in a separator right after a back pressure regulator which gives the nanoparticle high amount of available capping agent at a temperature far away from its decomposition temperature.

In an exemplary embodiment, such contact of nanoparticles with a large volume of capping agent stored within separator 620 may be beneficial due to the fact that there is a high amount of available capping agent for functionalization of the nanoparticles in comparison with an exemplary that the cold stream contains capping agent contact with the hot stream into the reactor. Because firstly there is limitation of dissolve capping agent in cold stream and secondly high concentration of the capping agent in the cold stream increases viscosity of the cold stream which leads to poor jet and mixing of cold and hot streams. Most of the capping agents may decomposed at higher temperature where a cold stream (ambient temperature) contacts to a hot stream (typically 450° C. or more) and produces a high temperature slurry stream at temperature around 370° C. While there is no chance of decomposition of capping agent after back pressure regulator at 100° C. (boiling point of water). Since most part of the slurry stream after the back pressure regulator is vaporized so the process produces only small amount of liquid including high concentration of functionalized nanoparticles (making slurry or dispersion which is so favorable) and there is no need a costly separation process for separation nanoparticles from a dilute suspension.

### EXAMPLE 1

In this example, a hydrothermal process similar to hydrothermal process 600 was used to produce zinc oxide nanoparticles. Here, a solution of 1.339 g Zn(NO₃)₂′6H₂O and 1.5 g PVP40 as modifier in 100 ml of water were prepared. The prepared solution was utilized as the cold metal salt solution. Process pressure was set at 240 bar by utilizing a back pressure regulator. Flow rates of the pumped fluids for the cold metal salt solution and the pure water stream were 4 and 8 mL/min, respectively. The injection pressure for the hot water was adjusted between 245 and 255 bar at temperatures between 380 and 420° C. to produce different zinc oxide nanoparticles dispersion at different temperatures. The pressure of the cold metal salt solution jet was 250 bar.

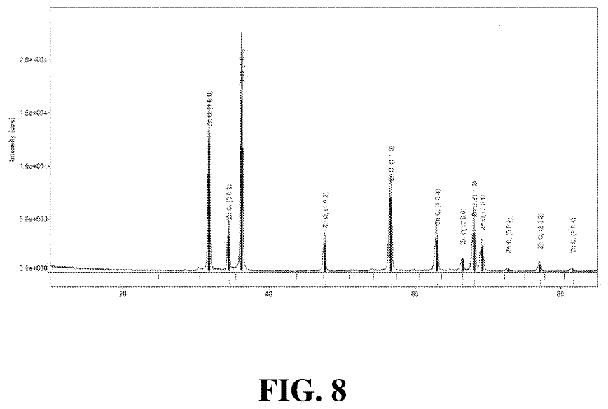

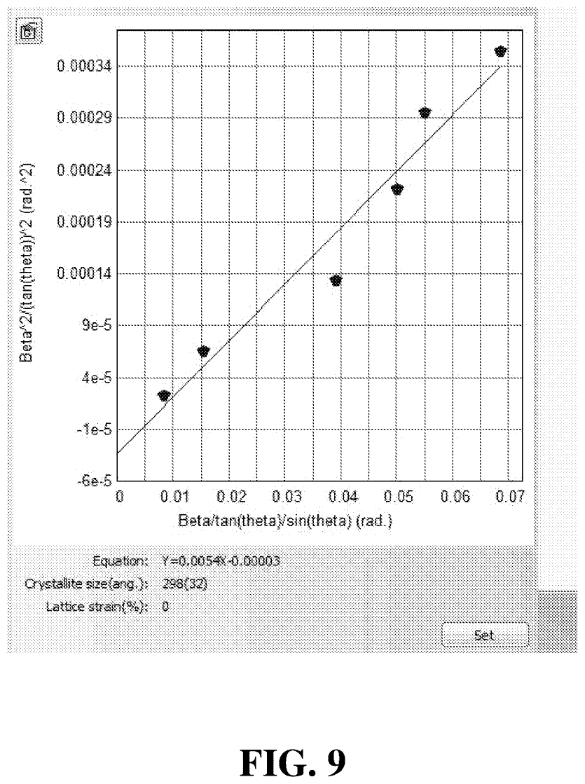

FIG. 8 Shows the X-ray diffraction (XRD) of the ZnO nanorods at a supercritical water temperature of 421° C., consistent with one or more exemplary embodiments of the present disclosure. As evident in FIG. 9, ZnO nanorods have been produced with average crystal size 29.8 nm.

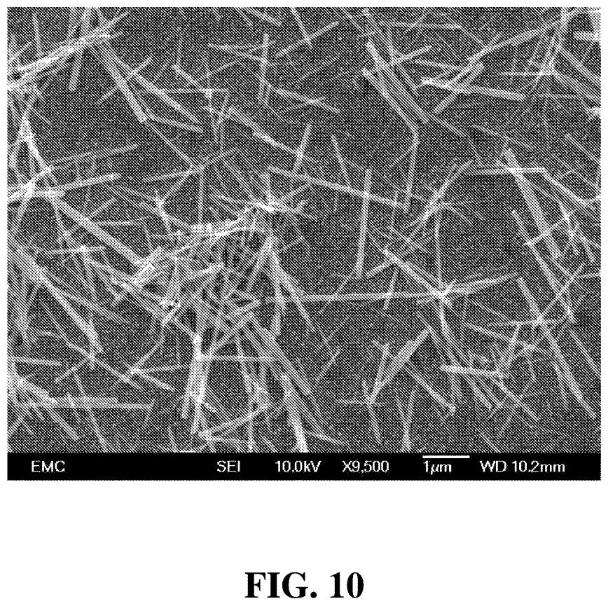

FIG. 9 shows the average crystal size ZnO nanorods at a supercritical water temperature of 421° C., consistent with one or more exemplary embodiments of the present disclosure. FIG. 10 shows scanning electron microscope (SEM) image of the ZnO nanorods at a supercritical water temperature of 421° C., consistent with one or more exemplary embodiments of the present disclosure. FIG. 10 shows the uniform distribution of nanorods with aspect ratio between 30 and 40. Average diameter of the nanorods are around 80-90 nm.

### EXAMPLE 2

In this example, a hydrothermal process similar to hydrothermal process 600 was used to produce iron oxide (Fe₂O₃) nanoparticles. Here, a solution of 3.636 g Fe(NO₃)₂′9H₂O and 1.5 g PVP40 as modifier in 100 mL of water were prepared. The prepared solution was utilized as the cold metal salt solution. Process pressure was set at 240 bar by utilizing a back pressure regulator. Flow rates of the pumped fluids for the cold metal salt solution and the pure water stream were 4 and 8 mL/min, respectively.

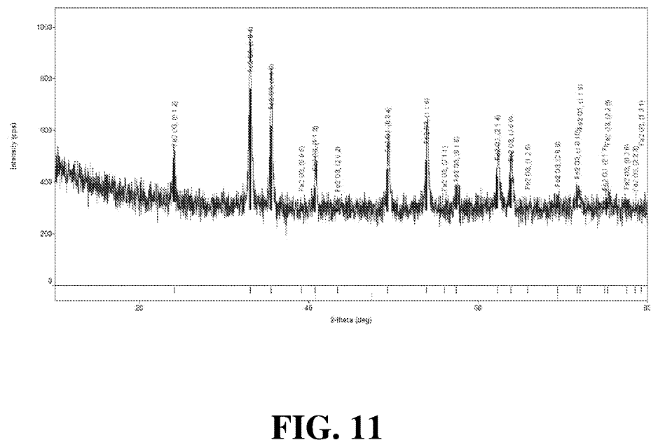

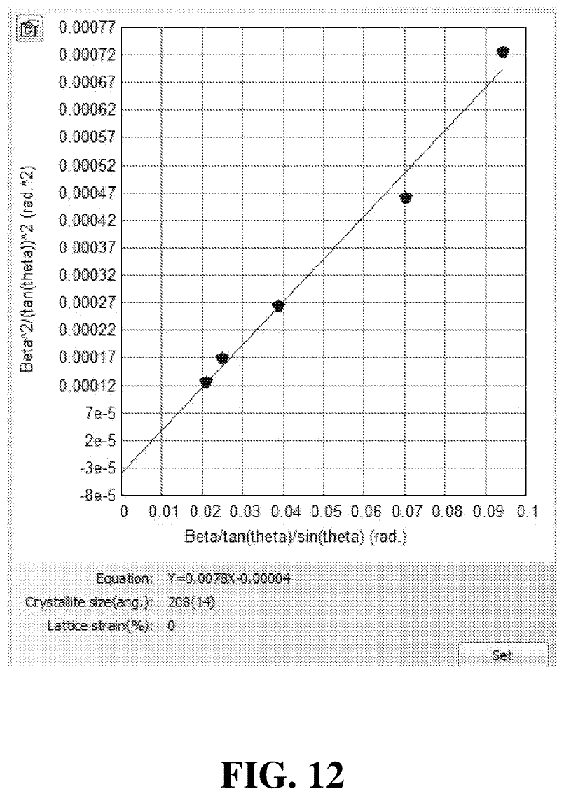

FIG. 11 shows the XRD of the Fe₂O₃ nanoparticles at supercritical water temperature of 402° C., consistent with one or more exemplary embodiments of the present disclosure. As evident from FIG. 12, Fe₂O₃ nanoparticles have been produced with an average crystal size of 20.8 nm.

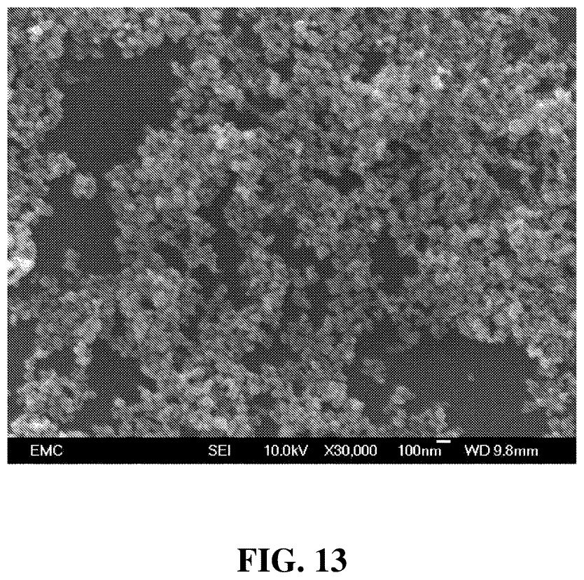

FIG. 12 shows the average crystal size Fe₂O₃ nanoparticles at supercritical water temperature of 402° C., consistent with one or more exemplary embodiments of the present disclosure. FIG. 13 shows SEM of Fe₂O₃ nanoparticles at supercritical water temperature of 402° C., consistent with one or more exemplary embodiments of the present disclosure. FIG. 13 shows the uniform distribution of Fe₂O₃ nanoparticles with average size 60 nm.

### EXAMPLE 3

In this example, a hydrothermal process similar to hydrothermal process 600 was used to produce Copper oxide (CU₃O₄) nanoparticles. Here, a solution of 0.73 g Cu(NO₃)₂′5H₂O and 1.5 g PVP40 as modifier in 100 ml of water were prepared. The prepared solution was utilized as the cold metal salt solution. Process pressure was set at 240 bar by utilizing a back pressure regulator. Flow rates of the pumped fluids for the cold metal salt solution and the pure water stream were 4 and 8 mL/min, respectively.

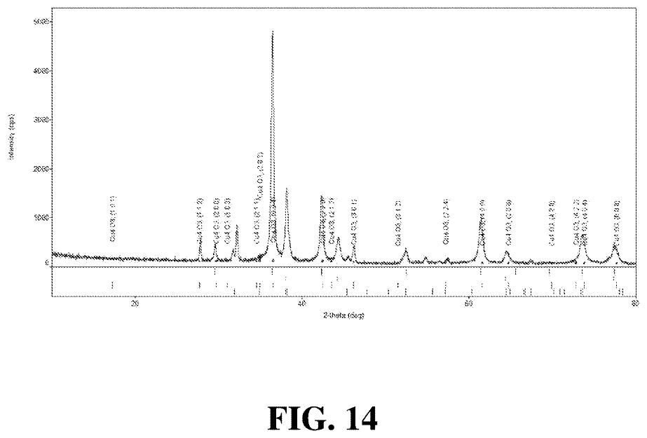

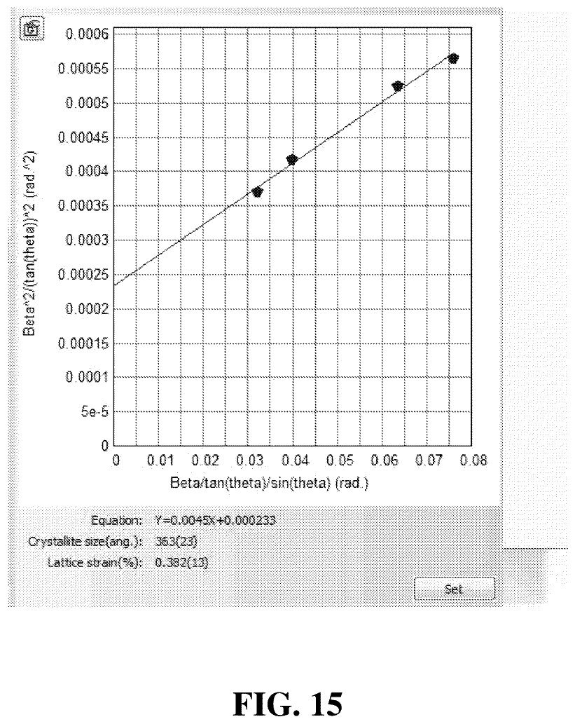

FIG. 14 shows the XRD of the CU₃O₄ nanoparticles at supercritical water temperature of 422° C., consistent with one or more exemplary embodiments of the present disclosure. FIG. 15 shows the average crystal size CU₃O₄ nanoparticles at supercritical water temperature of 422° C., consistent with one or more exemplary embodiments of the present disclosure. As evident from FIGS. 14 and 15, it is confirmed that CU₃O₄ nanoparticles have been produced with an average crystal size of 36.3 nm.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for description and not of limitation, such that the terminology or phraseology of the present specification is to be interpreted by the skilled artisan in light of the teachings and guidance.

The breadth and scope of the present disclosure should not be limited by any of the above-described exemplary embodiments but should be defined only in accordance with the following claims and their equivalents.

Throughout this specification and the claims which follow, unless the context requires otherwise, the word “comprise”, and variations such as “comprises” or “comprising”, will be understood to imply the inclusion of a stated integer or step or group of integers or steps but not to the exclusion of any other integer or step or group of integers or steps.

Moreover, the word “substantially” when used with an adjective or adverb is intended to enhance the scope of the particular characteristic, e.g., substantially planar is intended to mean planar, nearly planar and/or exhibiting characteristics associated with a planar element. Further use of relative terms such as “vertical”, “horizontal”, “up”, “down”, and “side-to-side” are used in a relative sense to the normal orientation of the apparatus.

1. A method for producing metal and metal oxide nanoparticles in a hydrothermal process, the method comprising:
obtaining a nanoparticle slurry by precipitating nanoparticles within a jet mixer reactor, the jet mixer reactor comprising:
an enclosure comprising an elongated side-wall extended along a longitudinal axis of the enclosure between a first end of the enclosure and an opposite second end of the enclosure;
a first inlet tube connected to the first end of the enclosure, the first inlet tube extended along the longitudinal axis of the enclosure, the first inlet tube in fluid communication with the enclosure;
a second inlet tube connected to the second end of the enclosure, the second inlet tube extended along the longitudinal axis of the enclosure, the second inlet tube in fluid communication with the enclosure; and
an outlet tube connected to the elongated side-wall of the enclosure, the outlet tube extended perpendicular to the longitudinal axis of the enclosure, the outlet tube in fluid communication with the enclosure,
wherein precipitating nanoparticles within the jet mixer reactor included:
injecting a metal salt solution jet into the enclosure by pumping the metal salt solution through the first inlet;
injecting a hot fluid jet into the enclosure by pumping the hot fluid through the second inlet tube, wherein the hot fluid jet collides with the metal salt solution jet within the enclosure; and
concurrently discharging the obtained nanoparticle slurry from the outlet tube.

2. The method of claim 1, wherein the jet mixer reactor further comprised a coiled tube connected in fluid communication with the outlet tube, wherein precipitating nanoparticles within the jet mixer reactor further comprised aging the discharged nanoparticle slurry within the coiled tube.

3. The method of claim 2, further comprising quenching the obtained nanoparticle slurry by passing the discharged nanoparticle slurry through a high-pressure back pressure regulator, wherein the nanoparticle slurry separates into a vapor phase and a liquid phase after passing through the high-pressure back pressure regulator.

4. The method of claim 3, further comprising functionalizing the nanoparticles by passing the vapor phase and the liquid phase through a high concentration of at least one of a water-based capping agent and a solvent-based capping agent.

5. The method of claim 4, wherein passing the vapor phase and the liquid phase through the high concentration of a water-based capping agent includes passing the vapor phase and the liquid phase through at least one of PVP, citric acid, and poly (ethylene glycol).

6. The method of claim 3, wherein injecting the metal oxide solution jet into the enclosure includes injecting the metal oxide solution jet at a temperature of at most 40° C. and at a pressure in a range of 70 to 400 bar through the first inlet.

7. The method of claim 6, wherein injecting the hot fluid jet into the enclosure includes injecting a supercritical waterjet through the second inlet.

8. The method of claim 6, wherein injecting the hot fluid jet into the enclosure includes injecting at least one of a hot alcohol jet and a mixture of water and alcohol jet through the second inlet.

9. The method of claim 8, wherein injecting the hot fluid jet into the enclosure includes injecting the hot fluid jet at a temperature in a range of 200° C. to 550° C. and at a pressure in a range of 70 to 400 bar through the second inlet.

10. The method of claim 1, which injecting the metal oxide solution jet into the enclosure comprising injecting the metal oxide solution jet into the enclosure in a first direction, which injecting the hot fluid jet into the enclosure comprising injecting the hot fluid jet into the enclosure in a second direction, and in which the first direction is opposite the second direction along the longitudinal axis of the enclosure.

11. The method of claim 10, wherein injecting the hot fluid jet into the enclosure includes injecting the hot fluid jet into the enclosure with a hot to cold flow ratio of between 1 and 5.

12. The method of claim 10, wherein injecting the hot fluid jet into the enclosure includes injecting the hot fluid jet into the enclosure with a velocity of at least 10 m/s.

13. The method of claim 10, wherein injecting the metal oxide solution jet into the enclosure includes injecting the metal oxide solution jet into the enclosure with a velocity of at least 3 m/s.

14. The method of claim 1, further comprising maintaining the temperature of cold metal oxide solution jet at a temperature of at most 40° C. by cooling the cold metal oxide solution jet within the first inlet tube, wherein cooling the cold metal oxide solution jet within the first inlet tube included providing a cold water jacket around the first inlet tube, at least a portion of an outer surface of the first inlet tube in contact with the cold water jacket.

15. The method of claim 1, injecting the metal oxide solution jet into the enclosure further comprising mixing the metal oxide solution with a capping agent, the capping agent comprising at least one of PVP, citric acid, and poly (ethylene glycol).

16. The method of claim 1, further comprising mixing the metal oxide solution with a base solution, the base solution comprising at least one of KOH and NaOH.
